(19) United States
(12) Patent Application Publication
(10) Pub. No.: US 2024/0304773 A1
(43) Pub. Date: Sep. 12, 2024

(54) CIRCUIT PANEL USING SIDE WALL WIRING AND METHOD OF FORMING SIDE WALL WIRING

(71) Applicant: APIOTECH CO., LTD., Gyeonggi-do (KR)

(72) Inventor: Byung Du OH, Gyeonggi-do (KR)

(21) Appl. No.: 18/547,645

(22) PCT Filed: Feb. 17, 2022
(86) PCT No.: PCT/IB2022/051416

§ 371 Date: Aug. 23, 2023

(30) Foreign Application Priority Data
Feb. 26, 2021 (KR) 10-2021-0026034

(51) Int. Cl. H01L 33/62; H01L 25/075; H01L 33/38

(52) U.S. Cl. CPC H01L 33/62; H01L 25/0753; H01L 33/382; H01L 2933/0016; H01L 2933/0066

(57) ABSTRACT

A circuit panel having side wirings comprises a substrate which includes a first circuit formed on a top surface of the substrate and a plurality of upper electrodes formed on one side of the top surface of the substrate corresponding to the first circuit, a side film adhered to the top surface, a side wall and a bottom surface of the substrate, with a plurality of conductive patterns formed parallel to each other on the side film, and a second circuit a plurality of lower electrodes connected to the conductive patterns to communicate with the first circuit, wherein an anisotropic conductive layer of the side film connect the conductive patterns to at least one of the upper electrodes and the lower electrodes.

### TECHNICAL FIELD

This invention relates to a method for electrically connecting one surface and the other surface of a circuit panel. more specifically, relates to a circuit panel that has wiring for circuit connections on its side, and a method for forming side wiring on the circuit panel.

### BACKGROUND ART

As electronic circuit devices are integrated and densely formed, there is a need to create multiple circuit layers on a single substrate. Korean Patent No. 10-0755615 includes using a double-sided printed circuit board made of resin material and connecting the printed circuit board with a connecting connector. As the number and density of components increase, it is common not only using one side of the circuit board, but also utilizing both sides of the circuit board or circuit panel. In the case of display panels or light-emitting panels, for example, light-emitting components are densely arranged on the surface of the panel, and in some cases, drive circuits are formed on the back or underneath the panel. There is a need to electrically connect the surface and the back of the panel and to form intricate wiring with high precision.

Conventionally, it was common to use a Flexible Printed Circuit Board (FPCB) to electrically connect the surface and back of a panel. However, the conventional FPCBs require a minimal bending radius when being bent from the surface to the back of the panel, and made it difficult to achieve bezel-less panels or to tightly adhere panels to each other on the same plane.

### DISCLOSURE

### Technical Problem

The present invention provides a method for forming side wiring that runs along the sidewalls of a panel to electrically connect the top side and the bottom side of a circuit panel.

The present invention provides a method and a circuit panel of forming side wiring without the need for expensive equipments, when connecting the circuits on both sides of the panel through the sides.

### Technical Solution

According to an exemplary embodiment of the present invention, a method for forming side wirings on a circuit panel, the circuit panel including a substrate, a first circuit formed on the upper surface of the substrate, and a plurality of upper electrodes formed on one side of the upper surface of the substrate corresponding to the first circuit, comprises steps of providing a second circuit on the lower side of or lower than the substrate and a plurality of lower electrodes formed on one side of the second circuit, providing a side film and a plurality of conductive patterns formed parallel to the side film, adhering the side film to the upper side, a side wall and a lower side of the substrate to allow the side film to cover the upper electrodes and the lower electrodes, and electrically connecting the upper electrodes and the lower electrodes using the conductive patterns, wherein an anisotropic conductive layer is used to connect the conductive patterns to at least one of the upper electrodes and the lower electrodes.

In this specification, when referring to a substrate, it includes not only general resin-based PCB substrates but also other substrate materials like glass substrates, sapphire substrates, and other glass materials. A double-sided circuit panel can be used to connect a first circuit and a second circuit through side wiring. The applications can include LED backlight substrates, micro LED displays, and more, for local dimming or zone dimming,

The anisotropic conductive layer may be formed using an anisotropic conductive adhesive, anisotropic conductive paste, or anisotropic conductive adhesive film.

The conductive patterns can utilize various types of conductive patterns, and since they are formed using the side film, it is possible to use a metal thick film with a thickness of about 1 to 20 μm or even thicker for their formation.

A pair of the upper electrode and the lower electrode can be electrically connected to each other, and the paired upper electrode and lower electrode may be connected by at least two or more conductive patterns. Furthermore, at least one dummy conductive pattern may exist at intervals of every adjacent groups of the conductive patterns connecting the upper electrodes and the lower electrodes. In here, the dummy conductive pattern is not connected to the first circuit and the second circuit.

When the width of the upper electrodes or lower electrodes is approximately 50 to 500 μm or more and the pitch of the electrodes is about 200 to 2000 μm or more, it can be advantageous to form the conductive patterns with such fine pitches.

Additionally, when the width of the upper electrodes or lower electrodes is approximately 20 to 150 μm or even smaller and the pitch of the electrodes is about 30 to 200 μm or another fine pitch, it can be advantageous to form the conductive patterns one-to-one.

The second circuit and the lower electrodes can be directly formed on the lower side of the substrate where the first circuit is formed. Alternatively, the second circuit and the lower electrodes can be formed on a different substrate from the one where the first circuit is formed.

The conductive patterns can be formed on the inner surface of the side film. In the case that the second circuit is formed on a different substrate, an extension substrate which includes a plurality of extension conductive patterns formed on the outer side corresponding to the conductive patterns and an adhesive layer formed on the inner side of the extension substrate. The conductive patterns can be formed using metal thick film, and the metal thick film can be formed using various methods such as etching, lift-off, thomson press cutting and the like.

The conductive patterns on the side film and the extension conductive patterns on the extension substrate can also be connected by an anisotropic conductive layer. As the extension substrate is adhered to the lower side of the circuit panel, the side film and the conductive patterns can be tightly adhered to the side of the circuit panel.

The side film can be separated from the conductive patterns and let the conductive patterns transferred onto the substrate. Of course, it is also possible to cover the upper surface, the side wall, and the lower side of the substrate without removing the side film. In this case, it is desirable for the side film to be formed from an insulating material.

According to an exemplary embodiment of the present invention, a circuit panel having side wirings may comprise a substrate which includes a first circuit formed on a top surface of the substrate and a plurality of upper electrodes formed on one side of the top surface of the substrate corresponding to the first circuit, a side film adhered to the top surface, a side wall and a bottom surface of the substrate, with a plurality of conductive patterns formed parallel to each other on the side film, and a second circuit including a plurality of lower electrodes connected to the conductive patterns to communicate with the first circuit, wherein an anisotropic conductive layer of the side film may connect the conductive patterns to at least one of the upper electrodes and the lower electrodes.

The anisotropic conductive layer can be formed using an anisotropic conductive adhesive, anisotropic conductive paste, or anisotropic conductive adhesive film. The conductive patterns can be formed using a metal thick film with a thickness of about 1 to 20 μm.

A pair of the upper electrode and the lower electrode can be electrically connected to each other, and the paired upper electrode and lower electrode may be connected by at least two or more conductive patterns. Furthermore, at least one dummy conductive pattern may exist at intervals of every adjacent groups of the conductive patterns connecting the upper electrodes and the lower electrodes. In here, the dummy conductive pattern is not connected to the first circuit and the second circuit. The dummy conductive patterns can block signal interference between electrically connected conductive patterns.

Additionally, the width of the conductive patterns can be uniformly formed. However, in different embodiments, the two end portions of the conductive pattern can be relatively narrower than the middle portion of the same conductive pattern, allowing the conductive patterns to be attached at a certain angle while still achieving proper electrical connections. The middle portion can be relatively wider as it passes through the side of the substrate, which can also help to reduce the resistance of each conductive pattern.

The conductive patterns can be formed on the inner surface of the side film, and a plurality of extension conductive patterns corresponding to the conductive patterns can be formed on the outer side of the extension substrate. An adhesive layer can be formed on the inner side of the extension substrate. The conductive patterns on the side film and the extension conductive patterns on the extension substrate can also be connected by an anisotropic conductive layer.

According to an exemplary embodiment of the present invention, the side film and the extension substrate can be combined and provided as an extension adapter. The extension adapter for side wirings can comprise a side film including a plurality of conductive patterns formed parallel to each other on an inner side of the side film, an extension substrate including extension conductive patterns formed on an outer side of the extension substrate corresponding to the conductive patterns, and an adhesive layer formed on an inner side of the extension substrate.

The extension substrate can be adhered to the bottom surface or the side of the circuit panel, allowing the side film and the conductive patterns to adhere to the side of the circuit panel.

In cases where circuit configuration on both sides of the panel is difficult, a separate substrate with the second circuit can be provided in addition to the substrate with the first circuit. By using an extension adapter, the extension substrate can be attached to the lower side of the original substrate using side wirings, and the second circuit can be separately connected to the attached extension substrate.

Here, the extension substrate can be a Flexible Printed Circuit Board (FPCB), PI (Polyimide) film, glass substrate, and other materials, and it can also be formed as a conventional PCB.

The conductive patterns on the side film and the extension conductive patterns on the extension substrate can be connected by an anisotropic conductive layer, and a release film can also be provided on the inner side of the adhesive layer.

### Advantageous Effects

According to the side wiring forming method of this invention, when it's impossible to create via holes or when high-density formation is required on one side of the substrate, circuit connections can be made through the side of the substrate, by functionally connecting circuits located on both sides of the substrate.

If the conductive patterns are formed using a metal thick film, they can be robustly structured, ensuring reliability, and reducing the resistance of the wiring.

### DESCRIPTION OF DRAWINGS

FIG. 1 is a view for illustrating a substrate of a circuit panel according to an embodiment of the present invention,

FIG. 2 is a view for explaining the cross-sectional structure of the circuit panel in FIG. 1,

FIG. 3 is a view for illustrating the disassembled structure of the circuit panel in FIG. 1,

FIG. 4 is a view for illustrating the cross-sectional structure of the circuit panel according to an embodiment of the present invention,

FIG. 5 is a view for explaining the electrical connection between the upper electrodes and the conductive patterns in the circuit panel according to an embodiment of the present invention,

FIG. 6 is a view for explaining the process of electrical connection in the circuit panel according to an embodiment of the present invention,

FIG. 7 is a view for explaining the extension adapter for side wiring according to an embodiment of the present invention, and

FIG. 8 is a view for explaining the process of electrical connection using the extension adapter for side wiring and the circuit panel according to an embodiment of the present invention.

### MODES OF THE INVENTION

Hereinafter, exemplary embodiments of the present invention will be described in detail with reference to the accompanying drawings, but the present invention is not limited or restricted to the exemplary embodiments. For reference, in the description, like reference numerals substantially refer to like elements, which may be described by citing contents disclosed in other drawings under such a rule and contents determined to be apparent to those skilled in the art or repeated may be omitted.

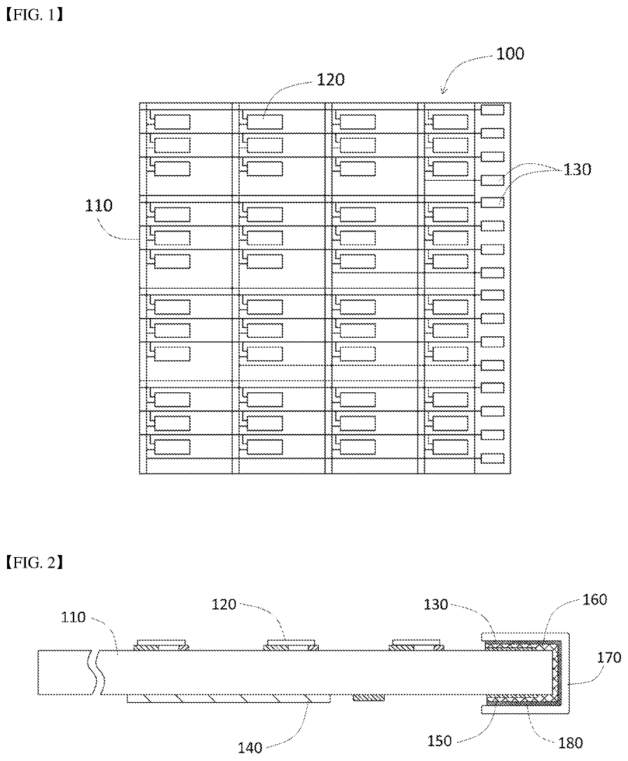

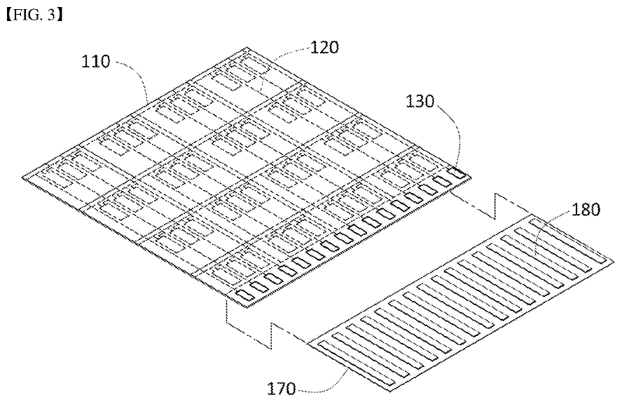

FIG. 1 is a view for illustrating a substrate of a circuit panel according to an embodiment of the present invention, FIG. 2 is a view for explaining the cross-sectional structure of the circuit panel in FIG. 1, and FIG. 3 is a view for illustrating the disassembled structure of the circuit panel in FIG. 1.

Referring FIGS. 1 to 3, a circuit panel according to this embodiment utilizes a double-sided circuit board with circuits formed on both the upper and lower surfaces. Wiring connections can be established on the side wall of the circuit panel. The circuit panel (100) comprises a substrate (110), a first circuit (120) formed on the upper surface of the substrate (110), a plurality of upper electrodes (130) formed on one side of the upper surface of the substrate (110) corresponding to the first circuit (120), a second circuit (140) formed on the lower side of the substrate (110), and a plurality of lower electrodes (150) formed on one side of the lower surface of the substrate (110) corresponding to the second circuit (140).

Moreover, to establish electrical and functional connections between the upper-side first circuit (120) and the lower-side second circuit (140), a multitude of conductive patterns (180) can be formed on a side film (170). The side film (170) can extend to cover either all or a portion of the upper electrodes (130) and the lower electrodes (150). It can extend around the edges of the side where the electrodes are formed, covering the upper side, the side wall, and lower side of the substrate (110). The inner side of the side film can accommodate the formation of conductive patterns (180) in a parallel manner.

In this embodiment, the substrate (110) can be formed from glass material. On the upper surface of the substrate (110), a first circuit (120) comprising luminescent elements like micro LEDs can be formed, while on the lower side, a second circuit (140) for driving these luminescent elements can be formed. Such double-sided circuit panels can also be utilized for applications like LED backlight boards for local dimming or zone dimming purposes.

Moreover, the upper electrodes (130) or lower electrodes (150) formed on the substrate (110) can be created using thin films or thick films of metals including copper, silver paste, molybdenum disulfide (MoS2), or silver nano wires. They can also be formed using materials like Oxide-Metal-Oxide (OMO).

As shown in FIG. 2, an anisotropic conductive layer (160) can be formed to attach the side film (170) with the conductive patterns (180) onto the substrate (110). The anisotropic conductive layer (160) can be provided in the form of adhesive, paste, or film, and it refers to a layer that is exclusively or primarily conductive in the thickness direction. For instance, conductive capsules can be incorporated into the layer to allow selective conductivity only at the compressed regions.

In FIG. 3, just as the upper electrodes (130) correspond to the conductive patterns (180) on the side film (170), they can be essentially formed with the same width and pitch. When the conductive patterns (180) are connected to the upper electrodes (130) and lower electrodes (150), a single conductive pattern (180) can link one pair of upper electrodes (130) and lower electrodes (150).

As the side film (170) formed with the conductive patterns (180) can be easily adhered by using the anisotropic conductive layer (160), it becomes feasible to facilitate the configuration of side wiring.

Furthermore, as shown in this embodiment, by using a polyimide film as the side film (170) and forming the conductive patterns (180) with a metal thick layer, it's possible to lower the overall resistance while allowing two right-angle bends in the side wiring. This approach minimizes the presence of protruding structures in the appearance.

The conductive patterns can be formed using various methods such as etching, lift-off, thomson press cutting and the like.

FIG. 4 is a view for illustrating the cross-sectional structure of the circuit panel according to an embodiment of the present invention.

Referring to FIG. 4, a circuit panel of this embodiment can be provided with or without the side film. To achieve this, the conductive patterns (180) are formed on the side film, then the conductive patterns (180) are attached to the substrate (110) along with the side film. Subsequently, the side film is removed from the substrate (110) while transferring the conductive patterns (180) to pass through top, side, and bottom surfaces of the substrate's (110).

As in the aforementioned embodiment, it is possible to protect the conductive patterns (180) without removing the film, but the film can also be removed, and additionally, a protective coating can be further formed after removing the film.

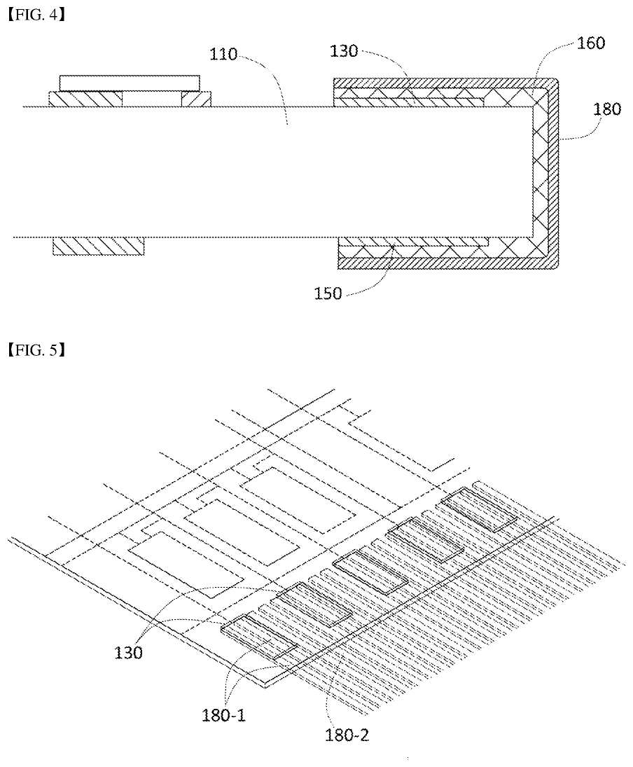

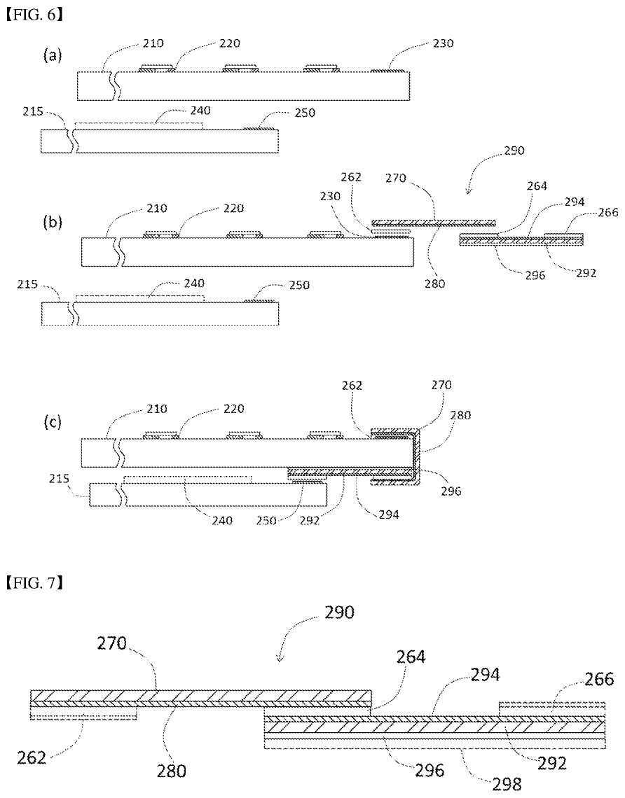

FIG. 5 is a view for explaining the electrical connection between the upper electrodes and the conductive patterns in the circuit panel according to an embodiment of the present invention.

Referring to FIG. 5, conductive patterns (180-1, 180-2) have a narrower width than the upper electrodes (130) or lower electrodes and are arranged more densely with smaller pitch. Therefore, when connecting the conductive patterns (180-1) to the upper electrodes (130) and lower electrodes, two or more conductive patterns (181-1) can be connected to the upper electrodes (130).

Therefore, even if one of the conductive patterns (180-1) connecting the electrodes becomes disconnected or damaged, it can still form a reliable electrical connection or establish a low resistance due to the parallel connection with other conductive patterns (180-1).

In this embodiment, the width of the upper electrode (130) or the lower electrode (150) can be formed around 50 to 500 μm, and the pitch of the electrodes (130, 150) can be around 200 to 2000 μm. In this case, the pitch of the conductive patterns (180-1) can be formed to be approximately 40 to 500μm, allowing 2 or more of the conductive patterns (180-1) to be connected to a single electrode.

However, if the width of the upper electrode or lower electrode is around 20 to 150 μm or less, and the pitch of the electrodes is around 30 to 200 μm or a finer pitch, as illustrated in FIG. 3, it might be more advantageous to form the conductive patterns one-to-one with the electrodes.

Furthermore, between the upper electrodes (130), there can exist a dummy conductive patterns (180-2) that are not connected to the upper electrodes. These can serve as a kind of dummy conductive pattern, which can help mitigate signal interference or noise between the surrounding conductive patterns (180-1).

Furthermore, even when aligning the side film and conductive patterns (180), a relatively low precision alignment can still reliably connect the upper electrodes (130) and lower electrodes (150) that correspond to each other. Of course, the conductive patterns are formed with a spacing smaller than the minimum gap between the upper and lower electrodes. Under the conditions described, where two or more conductive patterns connect corresponding upper and lower electrodes and at least one dummy conductive pattern exists between the connected conductive patterns without any electrical connection, the conductive patterns can also be formed with uneven spacing.

In this embodiment, two conductive patterns (180) can connect the upper electrodes (130) and lower electrodes (150) connected mutually, and a dummy conductive patterns can be provided without being connected with the upper electrodes (130) and the lower electrodes (150).

In this embodiment the width of the conductive patterns can be uniformly formed, but according to different embodiments, the end portions of the conductive patterns, especially those connecting to the electrodes, can be relatively narrow compared to the middle or remaining portions. By forming the ends of the conductive patterns relatively narrow in this way, even if the conductive patterns are attached crookedly at a certain angle during the process of attaching the insulating film to the side of the substrate, a satisfactory electrical connection can be achieved. Furthermore, by forming the middle part that passes through the side of the substrate relatively wide, the resistance of each conductive pattern can be reduced.

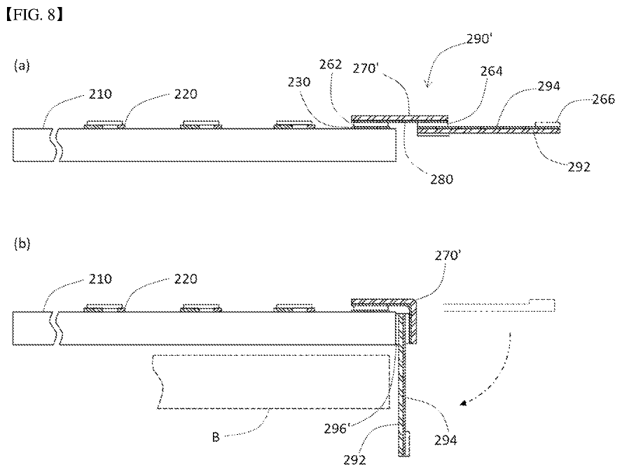

FIG. 6 is a view for explaining the process of electrical connection in the circuit panel according to an embodiment of the present invention, and FIG. 7 is a view for explaining the extension adapter for side wiring according to an embodiment of the present invention.

Referring to FIGS. 6 and 7, a circuit panel according to this embodiment utilizes a first substrate (210) on which only the first circuit (220) is formed on a top side. Additionally, a second substrate (215) on which a separate second circuit (240) is formed can be provided. Even in this case, side wiring connections can be established through the side wall of the substrate.

The circuit panel can include the first substrate (210) that has a plurality of upper electrodes (230) formed on the top side of the first substrate (210), corresponding to the first circuit (220) formed on the top side of the first substrate (210). Additionally, the independent second substrate (215) can be provided, on which the second circuit (240) is formed on the top side of the second substrate (215), corresponding to the second circuit (240) formed on the second substrate (215). The second substrate (215) can include a plurality of lower electrodes (250) formed on the top side of the second substrate (215).

Furthermore, to achieve electrical and functional connection between the first circuit (220) and the second circuit (240), an extension adapter (290) can be used to connect the upper electrodes (230) and lower electrodes (250).

Specifically, the extension adapter (290) can include a side film (270) with a plurality of conductive patterns (280) formed on it, a corresponding set of extension conductive patterns (294) formed on the opposite side extension substrate (292) in relation to the conductive patterns (280), and an adhesive layer (296) formed on the inner surface of the extension substrate (292), which contacts the underside of the first substrate (210) when folded.

The extension substrate (292) is adhered to the underside of the circuit panel, allowing the side film (270) and the conductive patterns (280) to be adhered to the sides of the first substrate (210).

When forming circuits on both sides of the first substrate (210), it is possible to achieve it using just the side film and conductive patterns. However, in cases where dual-sided circuit configuration of the first substrate (210) is not necessary or to reduce relative manufacturing costs, it could be advantageous to separately provide a second substrate (215) with a separate second circuit (240).

In such cases, the extension adapter (290) can be utilized to attach the extension substrate (292) to the underside of the first substrate (210) using side wiring. The exposed extension conductive patterns (294) on the attached extension substrate (292) can then be connected to the second circuit (240) through the lower electrodes (250).

The side film (270) or the extension substrate (292) can be made from materials such as FPCB, PI (polyimide) film, and can even be formed using standard PCB materials.

The area where the conductive patterns (280) of the side film (270) and the extension conductive patterns (294) of the extension substrate (292) are connected can be linked by an anisotropic conductive layer (264). Similarly, the regions where the conductive patterns (280) are connected to the upper electrodes (230) and the extension conductive patterns (294) are connected to the lower electrodes (250) can also be connected through anisotropic conductive layers (262, 266).

As shown in FIG. 7, when the extension adapter (290) is provided as a separate intermediate component, a release film (298) can be additionally provided on its inner side or lower side to protect the adhesive layer (296). In the case where the anisotropic conductive layer (262, 266) is an ACF (Anisotropic Conductive Film), the release film can also be attached and provided for ease of operation.

FIG. 8 is a view for explaining the process of electrical connection using the extension adapter for side wiring and the circuit panel according to an embodiment of the present invention.

Referring to FIG. 8, a circuit panel of this embodiment can utilize a first substrate (210) with only the first circuit (220) formed on the top surface. It's possible that a second substrate is not directly provided beneath the first substrate, and an example could involve different structures like a backlight (B). In this case, an extension substrate (292) of the extension adapter (290′) can be attached to the side of the first substrate (210), not to the lower surface. This configuration allows the formation of side wiring using the side film and the conductive patterns.

The extension adapter (290′) can include a side film (270′) with conductive patterns, an extension substrate (292) which extension conductive patterns (294) are formed on an outer side, and an adhesive layer (296′) adhered to an inner side of the extension substrate (292).

The extension substrate (292) can be adhered to the side of the circuit panel while simultaneously allowing the side film (270′) and conductive patterns to adhere to the side of the first substrate (210) and extend downward.

As described by referring to the preferred embodiments of the present invention, a person skilled in the art would understand that within the scope of the claims below, various modifications and changes can be made to the present invention without departing from the concepts and scope of the invention disclosed in the present invention.

1. A method of forming side wirings on a circuit panel, which includes a substrate, a first circuit formed on a top surface of the substrate, and a plurality of upper electrodes formed on one side of the top surface of the substrate corresponding to the first circuit, the method comprising steps of:
providing a second circuit provided at lower portion of the substrate and a plurality of lower electrodes formed on one side of the second circuit;
providing a side film and a plurality of conductive patterns formed parallel to each other on the side film;
adhering the side film to the one side of the top surface, a side wall, the one side of the bottom surface of the substrate to cover the upper electrodes and the lower electrodes; and
electrically connecting the upper electrodes and the lower electrodes using the conductive patterns;
wherein an anisotropic conductive layer of the side film connect the conductive patterns to at least one of the upper electrodes and the lower electrodes.

2. The method of claim 1, wherein the anisotropic conductive layer is formed using an anisotropic conductive adhesive, anisotropic conductive paste, or anisotropic conductive adhesive film.

3. The method of claim 1, wherein the conductive patterns are formed using a metal thick film.

4. The method of claim 1, wherein a pair of the upper electrode and the lower electrode electrically connected to each other are connected by at least two or more conductive patterns, and at least one dummy conductive pattern exists at intervals of adjacent groups of the conductive patterns connecting the upper electrodes and the lower electrodes, and
wherein the dummy conductive pattern is not connected to the first circuit and the second circuit.

5. The method of claim 1, wherein the second circuit and the lower electrodes are formed on the bottom surface of the substrate.

6. The method of claim 1, wherein the second circuit and the lower electrodes are formed on another substrate different from the substrate on which the first circuit and the upper electrodes are formed.

7. The method of claim 6, wherein the conductive patterns are formed on an inner surface of the side film,
an extension substrate is provided with an outer surface on which extension conductive patterns are formed corresponding to the conductive patterns and an inner surface on which an adhesive layer is formed,
the conductive patterns of the side film and the extension conductive patterns of the extension substrate are electrically connected with an anisotropic conductive layer, and
the extension substrate is adhered to the bottom surface or the side of the circuit panel, allowing the side film and the conductive patterns to adhere to the side of the circuit panel.

8. The method of claim 1, further comprising a step of transferring the conductive patterns to the substrate, by separating the side film and remaining the conductive patterns on the side of the substrate.

9. The method of claim 1, wherein the two end portions of conductive patterns relatively narrower than the middle portion of conductive patterns.

10. A circuit panel having side wirings, comprising:
a substrate including a first circuit formed on a top surface of the substrate and a plurality of upper electrodes formed on one side of the top surface of the substrate corresponding to the first circuit;
a side film adhered to the top surface, a side wall and a bottom surface of the substrate, with a plurality of conductive patterns formed parallel to each other on the side film; and
a second circuit including a plurality of lower electrodes connected to the conductive patterns to communicate with the first circuit;
wherein an anisotropic conductive layer of the side film connect the conductive patterns to at least one of the upper electrodes and the lower electrodes.

11. The circuit panel of claim 10, wherein the anisotropic conductive layer is formed using an anisotropic conductive adhesive, anisotropic conductive paste, or anisotropic conductive adhesive film.

12. The circuit panel of claim 10, wherein the conductive patterns are formed using a metal thick film.

13. The circuit panel of claim 10, wherein a pair of the upper electrode and the lower electrode electrically connected to each other are connected by at least two or more conductive patterns, and at least one dummy conductive pattern exists at intervals of adjacent groups of the conductive patterns connecting the upper electrodes and the lower electrodes, and
wherein the dummy conductive pattern is not connected to the first circuit and the second circuit.

14. The circuit panel of claim 10, wherein the second circuit and the lower electrodes are formed on the bottom surface of the substrate.

15. The circuit panel of claim 10, wherein the second circuit and the lower electrodes are formed on another substrate different from the substrate on which the first circuit and the upper electrodes are formed.

16. The circuit panel of claim 15, wherein the conductive patterns are formed on an inner surface of the side film,
an extension substrate is provided with an outer surface on which extension conductive patterns are formed corresponding to the conductive patterns and an inner surface on which an adhesive layer is formed,
the conductive patterns of the side film and the extension conductive patterns of the extension substrate are electrically connected with an anisotropic conductive layer, and
the extension substrate is adhered to the bottom surface or the side of the circuit panel, allowing the side film and the conductive patterns to adhere to the side of the circuit panel.

17. The circuit panel of claim 10, wherein the two end portions of conductive patterns relatively narrower than the middle portion of conductive patterns.

18. An extension adapter added to a circuit panel which includes a substrate, a first circuit formed on a top surface of the substrate and a plurality of upper electrodes formed on one side of the top surface of the substrate corresponding to the first circuit, to form side wirings connecting the first circuit and another circuit except the first circuit, the extension adapter comprising:
a side film including a plurality of conductive patterns formed parallel to each other on an inner side of the side film;
an extension substrate including extension conductive patterns formed on an outer side of the extension substrate corresponding to the conductive patterns; and
an adhesive layer formed on an inner side of the extension substrate;
wherein the extension substrate is adhered to the bottom surface or the side of the circuit panel, allowing the side film and the conductive patterns to adhere to the side of the circuit panel.

19. The extension adapter of claim 18, wherein an anisotropic conductive layer connects the conductive patterns of the side film and the extension conductive patterns of the extension substrate.

20. The extension adapter of claim 18, wherein a release film is provided on the inner side of the adhesive layer.
